(19) United States
(12) Patent Application Publication
(10) Pub. No.: US 2011/0221303 A1
(43) Pub. Date: Sep. 15, 2011

(54) ELECTRONIC DEVICE

(75) Inventor: Seiichi CHIBA, Minowa-machi (JP)

(73) Assignee: SEIKO EPSON CORPORATION, Tokyo (JP)

(21) Appl. No.: 13/036,436

(22) Filed: Feb. 28, 2011

(30) Foreign Application Priority Data
Mar. 12, 2010 (JP) 2010-055974

(51) Int. Cl. H01L 41/04

(52) U.S. Cl. 310/313 R

(57) ABSTRACT

An electronic device includes: a base substrate having a resonator element fixed to one of principal surfaces, and provided with at least one lead wire; a frame member having a substantially rectangular shape, disposed on the one of the principal surfaces so as to surround a periphery of the resonator element, wherein side surface of the base substrate is provided with a side surface recessed section having a terminal electrically connected to the lead wire, and the side surface recessed section is disposed on the side surface of the base substrate on a side where the resonator element is fixed, at a position where at least a part of the side surface recessed section overlaps an area between two extended lines passing through respective outer side surfaces of the frame member opposed to each other in a plan view from the one of the principal surfaces of the base substrate.

### BACKGROUND

1. Technical Field

The present invention relates to an electronic device to be mounted to electronic apparatuses.

2. Related Art

Electronic devices having electronic components on a substrate are widely used for electronic apparatuses such as portable terminals or mobile phones. In accordance with downsizing and low-profiling of electronic apparatuses, downsizing and low-profiling are required for various types of electronic devices. In JP-A-2009-27465 (Document 1) there is disclosed an example of an electronic device achieving such downsizing.

FIGS. 5A and 5B are cross-sectional view of a crystal oscillator described in Document 1 and plan view thereof except a cover, respectively. As shown in the drawings, the crystal oscillator according to Document 1 has a container main body 100 formed of a laminated ceramic composed of a bottom plate 100a and a frame wall 100b, the container main body 100 being provided with a recessed section 120 and a planar section 130. A crystal piece 140 is fixed to holding terminals inside the recessed section 120 with an electrically conductive adhesive 122, and is covered by the cover 142. Further, an IC chip 134 is fixed to circuit terminals 132 on a surface of the planar section 130 by flip-chip bonding. Further, the planar section 130 is provided with crystal test terminals 136 for independently measuring the resonation characteristics of a resonator composed of the resonator element and the IC chip 134. Further, after the flip-chip bonding of the IC chip 134, protective resin 138 for the IC chip 134 is applied thereon (not shown in FIG. 5B). On this occasion, the protective resin 138 is provided on the entire surface of the planar section 130 including the crystal test terminals 136.

According to the configuration described above, the crystal piece and the IC chip are arranged in a horizontal direction, thereby making it possible to achieve low-profiling. Further, since the configuration of hermetically encapsulating the crystal piece in the recessed section 120, and fixing the IC chip 134 to the planar section 130 separately therefrom is adopted, it is possible to dispose defective crystal resonator in advance to thereby improve the yield, and enhance the productivity.

However, such a crystal oscillator as described in Document 1 has the crystal terminals on the IC mounting surface, and if the protective resin is applied, the crystal terminals are covered by the protective resin and are no more exposed to the outside. Further, according to Document 1, if an oscillation failure occurs after shipment, the resonation characteristics of the crystal resonator can be checked after removing the protective resin. However, the operation of removing and then reapplying the protective resin formed on the narrow place will be troublesome.

As a configuration of avoiding providing the crystal terminals to the planar section of the container main body as described above, it is possible to adopt a configuration of providing a castellation to a side surface of a base substrate to constitute the container main body, and providing the crystal terminals to the side surface.

However, after mounting the crystal oscillator, which has the resonator element and the IC chip mounted in a horizontal direction, on a user board, the stress is apt to be concentrated at the center of the base substrate, specifically in the direction of the cross-section passing through the longitudinal center of the substrate, due to the bending strength to the user board. Therefore, depending on the location of the castellation described above, a crack might be caused easily in the base substrate.

### SUMMARY

An advantage of some aspects of the invention is to provide an electronic device capable of achieving the low-profiling of the entire device, and at the same time reducing the stress of the substrate by stabilizing the connection with the resonator element and so on.

The invention can solve at least a part of the problem described above, and can be implemented as the following embodiment examples.

### Application Example 1

This application example of the invention is directed to an electronic device including a resonator element, a base substrate having a substantially rectangular shape, having the resonator element fixed to one of principal surfaces, having a mounting terminal formed on the other of the principal surfaces, and provided with a lead wire, a frame member having a substantially rectangular shape, disposed on the one of the principal surfaces so as to surround a periphery of the resonator element, and a lid member adapted to cover an opening of the frame member, wherein a side surface of the base substrate is provided with a side surface recessed section having a terminal electrically connected to the lead wire, and the side surface recessed section is disposed on the side surface of the base substrate on a side where the resonator element is fixed, at a position where at least a part of the side surface recessed section overlaps an area between two extended lines passing through respective outer side surfaces of the frame member opposed to each other in a plan view from the one of the principal surfaces of the base substrate.

According to the configuration described above, the box-like structure composed of the frame member and the lid member is provided to the resonator element side of the base substrate, thus the base substrate can be reinforced. Since the side surface recessed section is formed so that at least a part of the side surface recessed section overlaps the area between the extended lines passing through the outer side surfaces of the frame member opposed to each other, it is possible to effectively prevent the phenomenon that the stress is concentrated to the side surface recessed section to cause a crack. Further, since the terminal of the side surface recessed section is exposed to the outside even after the electronic device is coated with the resin material, frequency adjustment or the like of the resonator element can easily be performed.

### Application Example 2

This application example of the invention is directed to the electronic device of the application example 1 of the invention, wherein the side surface recessed section is disposed on the side surface of the base substrate on the side where the resonator element is fixed, in the area between the two extended lines passing through the respective outer side surfaces of the frame member opposed to each other in a plan view from the one of the principal surfaces of the base substrate.

According to the configuration described above, since the side surface recessed section is formed within the area between the extended lines passing through the outer side surfaces of the frame member opposed to each other, it is possible to more effectively prevent the phenomenon that the stress is concentrated to the side surface recessed section to cause a crack.

### Application Example 3

This application example of the invention is directed to the electronic device of the application example 1 of the invention, wherein the side surface recessed section is disposed on the side surface of the base substrate on the side where the resonator element is fixed, within an area between two extended lines passing through respective inner side surfaces of the frame member opposed to each other in a plan view from the one of the principal surfaces of the base substrate.

According to the configuration described above, since the side surface recessed section is formed within the area between the extended lines passing through the inner side surfaces of the frame member opposed to each other, it is possible to effectively prevent the phenomenon that the stress is concentrated to the side surface recessed section to cause a crack.

### Application Example 4

This application example of the invention is directed to the electronic device of any one of the application examples 1 to 3 of the invention, wherein the frame member is a metal ring.

According to the configuration described above, the substrate strength of the resonator element side of the base substrate can easily be assured.

### Application Example 5

This application example of the invention is directed to the electronic device of any one of the application examples 1 to 4 of the invention, wherein the lid member is a metal lid.

According to the configuration described above, the box-like structure is formed with the metal ring, and thus the substrate strength of the resonator element side of the base substrate can easily be assured.

### Application Example 6

This application example of the invention is directed to the electronic device of any one of the application examples 1 to 5 of the invention, wherein the resonator element and an electronic component are arranged on the one of the principal surfaces of the base substrate in a longitudinal direction of the base substrate.

According to the configuration described above, low-profiling of the entire device can be achieved.

### Application Example 7

This application example of the invention is directed to the electronic device of the application example 6 of the invention, wherein the side surface recessed section is provided alone to the side surface on the resonator element side of the base substrate.

According to the configuration described above, it is possible to effectively prevent the phenomenon that the stress is concentrated to the side surface recessed section to cause a crack.

### BRIEF DESCRIPTION OF THE DRAWINGS

The invention will be described with reference to the accompanying drawings, wherein like numbers reference like elements.

FIGS. 1A and 1B are diagrams showing a schematic configuration of an electronic device according to an embodiment of the invention, wherein FIG. 1A is a cross-sectional view, and FIG. 1B is a plan view.

FIGS. 2A through 2D are explanatory diagrams of a base substrate, wherein FIG. 2A is a plan view of a first substrate, FIG. 2B is a plan view of a second substrate, FIG. 2C is a plan view of a third substrate, and FIG. 2D is a bottom view of the third substrate.

FIG. 3A is a diagram for explaining conditions of a stress simulation, and FIG. 3B is a diagram showing a result of the simulation.

FIGS. 4A through 4C are explanatory diagrams of side surface recessed sections provided to the base substrate.

FIGS. 5A and 5B are diagrams showing a schematic configuration of an electronic device of the related art, wherein FIG. 5A is a cross-sectional view, and FIG. 5B is a plan view.

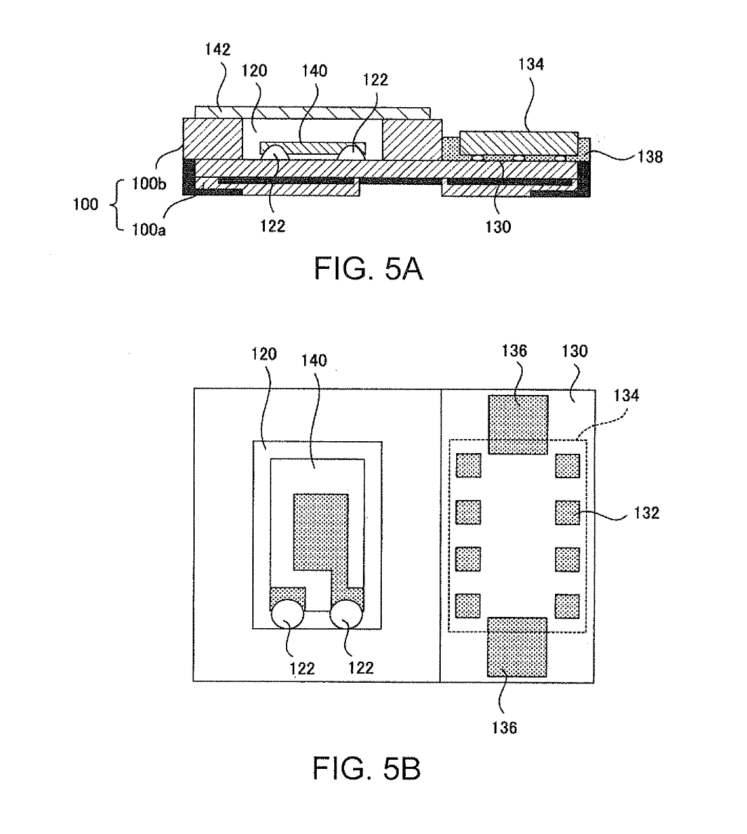

### DESCRIPTION OF AN EXEMPLARY EMBODIMENT

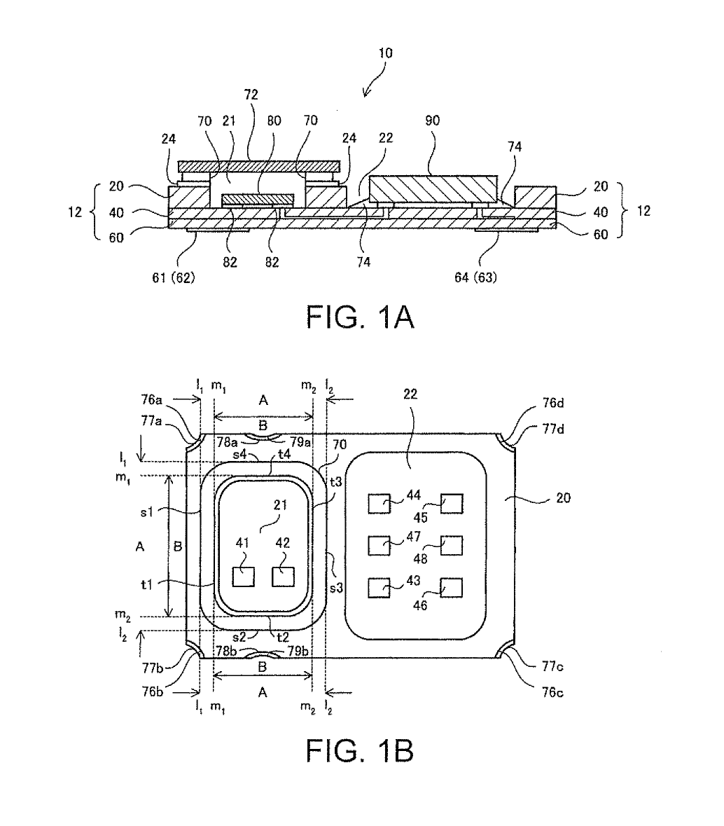

Hereinafter an electronic device according to an embodiment of the invention will be explained in detail with reference to the accompanying drawings. FIGS. 1A and 1B are diagrams showing a schematic configuration of the electronic device 10 according to the present embodiment. FIG. 1A shows a side cross-sectional view of the electronic device, and FIG. 1B shows a plan view (except lead electrodes) of the base substrate. As shown in the drawings, the electronic device 10 according to the present embodiment is composed of a resonator element 80, an IC chip 90, first through third substrates 20, 40, and 60 constituting the base substrate 12.

As the resonator element 80 to be mounted to the electronic device 10, a crystal resonator element such as a tuning-fork crystal resonator element can be used. It should be noted that the resonator element 80 can be an AT-cut crystal resonator element, an surface acoustic wave crystal resonator element, and so on besides the tuning-fork type. Further, as the material of the resonator element, lithium tantalate, lithium niobate, and so on can also be used besides the quartz crystal. Further, it is also possible to use various types of resonator element other than the piezoelectric resonator element instead of the crystal resonator element, and for example, a micro electromechanical systems (MEMS) resonator element formed by processing a silicon substrate can also be used.

As the IC chip 90 to be an electronic component, an integrated circuit or the like composed of semiconductor elements having a circuit structure for oscillating the resonator element can be used. On one of the surfaces of the IC chip 90, there is formed a plurality of electrode pads (not shown) including, for example, input-output terminals, control terminals for writing data into an oscillating circuit, and ground terminals.

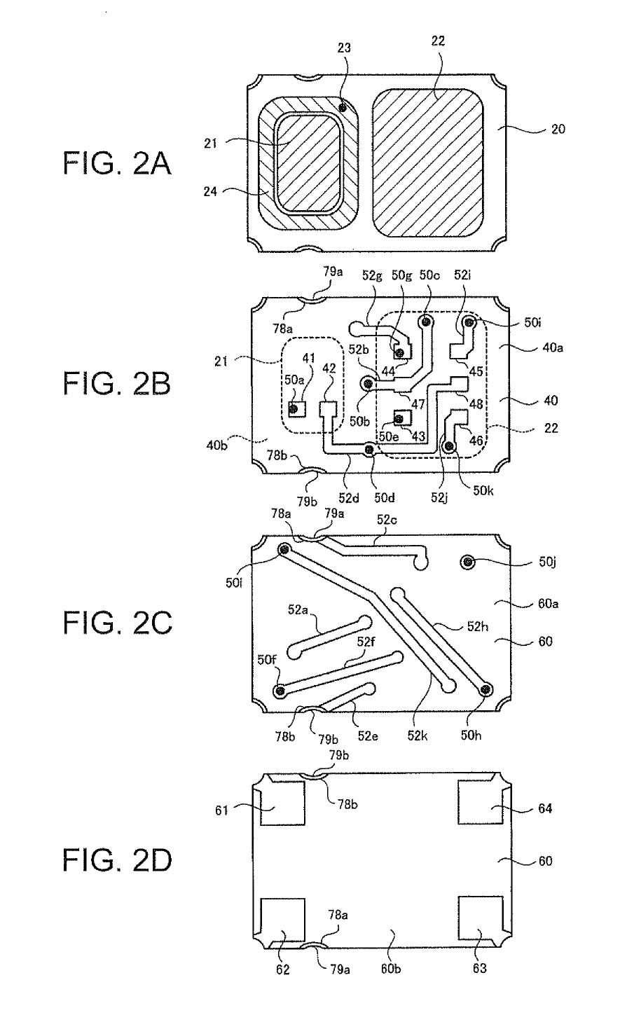

FIGS. 2A through 2D are explanatory diagrams of the base substrate 12. FIG. 2A is a plan view of a first substrate, FIG. 2B is a plan view of a second substrate, FIG. 2C is a plan view of a third substrate, and FIG. 2D is a bottom view of the third substrate. As shown in the drawings, the first through third substrates 20, 40, and constituting the base substrate 12 are plate-like substrates having a substantially rectangular shape in a plan view when being stacked to each other. The first through third substrates 20, 40, and 60 are each formed using various types of insulating materials, and in the present embodiment, ceramic is used therefor.

The first substrate 20 is the uppermost layer of the substrates constituting the base substrate 12, and forms first and second recessed sections 21, 22 surrounding the periphery of the resonator element 80 and the IC chip 90. The first recessed section 21 forms an internal space for housing the resonator element 80 inside, and is provided with a via-hole 23 formed at a location of a frame member 70 described later. The second recessed section 22 forms a space for housing the IC chip 90 inside. A bonding surface for the frame member 70, the outer periphery of the first recessed section 21, is coated with a metal brazing material 24. It should be noted that the first substrate 20 is formed to have a thickness larger than at least the thickness of the resonator element 80.

The second substrate 40 is an intermediate layer of the substrates constituting the base substrate 12. The second substrate 40 is provided with resonator element mounting terminals (41, 42) to be electrically connected to the resonator element 80 and IC chip mounting terminals (43, 44, 45, 46, 47, and 48) to be electrically connected to the IC chip 90, formed on a first principal surface 40a to be bonded to the first substrate 20. Further, the resonator element mounting terminals and the IC chip mounting terminals are provided with lead wires (52b, 52d, 52g, 52i, and 52j) for providing electrical connections to mounting terminals (61, 62, 63, and 64) described later, and further, the resonator element mounting terminals, the IC chip mounting terminals, and the lead wires are provided with via-holes (50a, 50b, 50c, 50d, 50e, 50g, 50i, and 50k) penetrating the second substrate from the first principal surface 40a to the second principal surface 40b. It should be noted that in FIG. 2B the areas corresponding to the recessed sections 21, 22 are indicated by broken lines.

The resonator element mounting terminals are composed of first and second resonator element mounting terminals 41, 42 to be electrically connected to a pair of excitation electrodes (not shown) of the resonator element 80 via an electrically conductive adhesive 82.

The IC chip mounting terminals include, as an example, mounting electrodes for mounting resonator element connection terminals of the integrated circuit, power supplying electrodes, stand-by (ST) electrodes, signal output electrodes, grounding electrodes, and so on, and are composed of first through sixth IC chip mounting terminals (43, 44, 45, 46, 47, and 48).

The third substrate 60 is the lowermost layer of the substrates constituting the base substrate 12, and is provided with lead wires (52a, 52c, 52e, 52f, 52h, and 52k) for providing electrical connection to the via-holes formed in the second substrate 40, formed on the first principal surface 60a to be bonded to the second substrate 40. The third substrate 60 is provided with first through fourth mounting terminals 61, 62, 63, and 64 formed on the other principal surface 60b on the four corners thereof. Some of the lead wires on the first principal surface 60a and the mounting terminals on the second principal surface 60b are electrically connected to each other via via-holes (50f, 50h, 50j, and 50l) penetrating the third substrate from the first principal surface 60a to the second principal surface 60b.

The frame member 70 is a frame-like reinforcing member along the outer periphery of the first recessed section 21 of the first substrate 20. The frame member 70 is a member for reinforcing the first recessed section 21 for housing the resonator element 80 to be mounted on the base substrate 12. By forming the frame member 70 with a material having rigidity higher than that of the base substrate 12, the effectiveness of reinforcing the first recessed section 21 can further be enhanced. In the present embodiment, a metal ring, which is a frame member made of metal having rigidity higher than that of the ceramic forming the base substrate 12, is used as the frame member 70.

A lid member 72 is a member for covering the opening of the frame member 70 of the first substrate 20. The lid member 72 can be a plate-like lid or a hat-like lid having a flange section along the outer periphery of the first recessed section 21. In the present embodiment, a plate-like metal lid is used as the lid member.

In the base substrate according to the present embodiment, the resonator element side of the base substrate 12 is reinforced by a box-like structure composed of the frame member 70 and the lid member 72, and therefore, the stress caused in the base substrate 12 by an external force can be reduced.

A resin member 74 is a member formed between the outer periphery of the IC chip 90 and the second substrate having the IC chip 90 mounted thereon. The resin member 74 has an insulating property, and mold resin can be used therefor as an example.

The base substrate 12 has corner castellations (76a, 76b, 76c, and 76d) formed on the four corners. The corner castellations (76a, 76b, 76c, and 76d) are each formed by cutting the corner of the base substrate 12 having a rectangular planar shape so as to have a quadrant shape. The side surfaces of the corner castellations (76a, 76b, 76c, and 76d) on the four corners are provided with terminals (77a, 77b, 77c, and 77d) formed so as to be drawn from the respective mounting terminals (61, 62, 63, and 64) formed on the four corners of the third substrate 60.

Unlike the corner castellations (76a, 76b, 76c, and 76d) formed on the corners of the base substrate 12, side surface recessed sections (78a, 78b) are provided to the side surfaces of the base substrate 12 having the first through third substrates stacked with each other so as to have a semicircular cross-sectional shape. The side surface recessed sections (78a, 78b) form side surface terminals (79a, 79b) to be electrically connected to lead wires (52c, 52e) described later. The side surface recessed sections (78a, 78b) form the side surface terminals (79a, 79b), and are therefore formed with predetermined distances from the corner castellations (76a, 76b, 76c, and 76d) on the four corners so as not to have electrical contact with the terminals 77a through 77d of the corner castellations (76a, 76b, 76c, and 76d).

Here, as described above, after mounting the crystal oscillator, which has the resonator element and the IC chip mounted in a horizontal direction, on a user board, the stress is apt to be concentrated at the center of the base substrate, specifically in the direction of the cross-section passing through the longitudinal center of the substrate, due to the bending strength to the user board. Therefore, depending on the locations of the side surface recessed sections (78a, 78b), there is a possibility that the stress is concentrated, and the crack is apt to occur in the base substrate 12. Therefore, the inventors conducted a simulation with respect to the locations of the side surface recessed sections (78a, 78b).

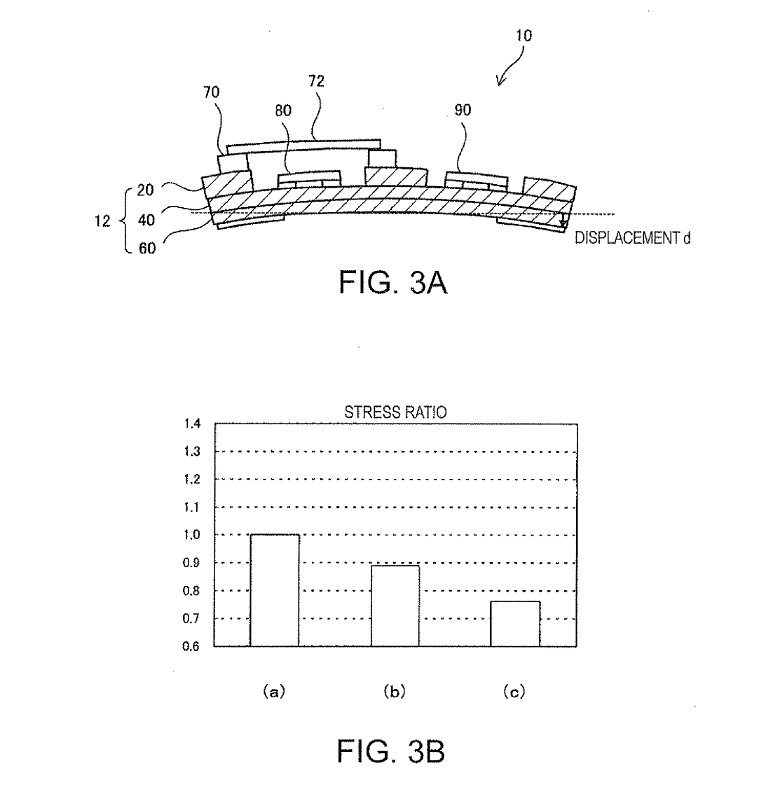

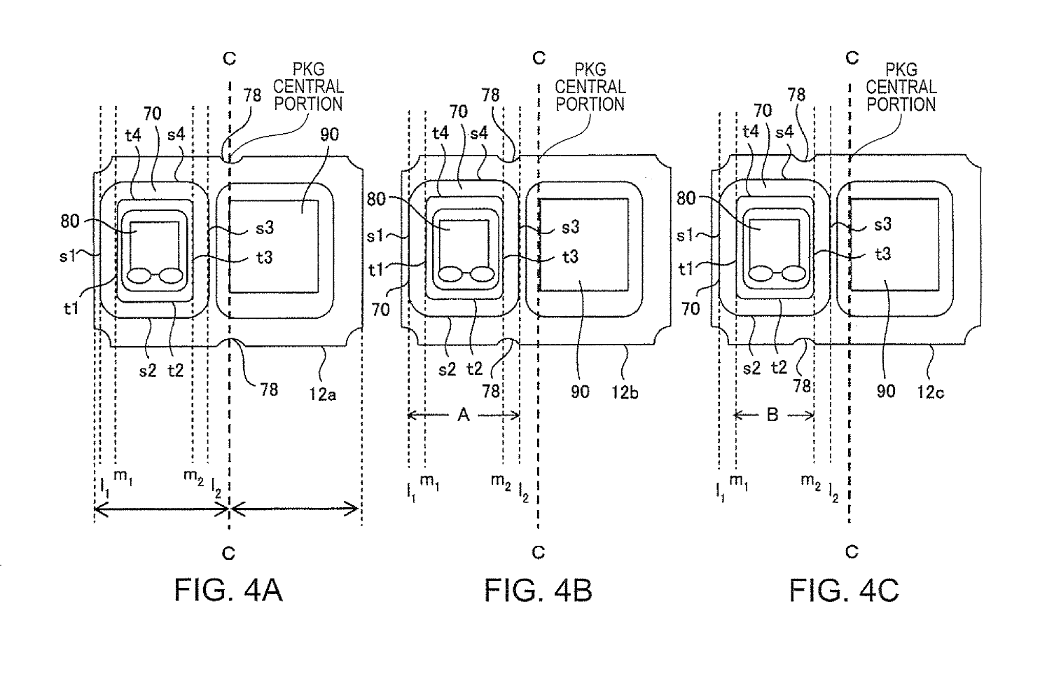

FIG. 3A is a diagram for explaining conditions of the stress simulation, and FIG. 3B is a diagram showing the result of the simulation. FIGS. 4A through 4C are explanatory diagrams of the side surface recessed sections provided to the base substrate.

As shown in FIG. 3A, the stress acting on the base substrate 12 of the electronic device mounted to the user board due to the bending strength of the user board is apt to act on the longitudinal center of the base substrate 12 in a direction intersecting the longitudinal direction. Therefore, the maximum stress caused at the center portion of the base substrate 12 in the case in which a certain displacement “d” is caused in the base substrate 12 due to the deformation of the user board is calculated by the stress simulation.

Here, the electronic device shown in FIG. 4A is a device having the pair of side surface recessed sections 78 formed in a direction passing through the longitudinal center of the base substrate and intersecting the longitudinal direction thereof, in other words, on the center line C-C passing through the central portion of the package. The electronic device having the configuration described above has the side surface recessed sections 78 formed on the center line C-C passing through the central portion of the package, and is therefore apt to receive the maximum stress caused in the base substrate 12a.

Further, the electronic device shown in FIG. 4B is a device having the pair of side surface recessed sections 78 formed at positions inside an area A between extended lines l₁ and l₂, which pass through the outer side surfaces (s1, s3) of the frame member 70 of the base substrate 12b substantially perpendicular to the longitudinal direction of the electronic device out of the outer side surfaces (s1, s2, s3, and s4) thereof, and having contact with the line l₂.

Further, the electronic device shown in FIG. 4C is a device having the pair of side surface recessed sections 78 formed at positions inside an area B between extended lines m₁ and m₂, which pass through the inner side surfaces (t1, t3) of the frame member 70 of the base substrate 12c substantially perpendicular to the longitudinal direction of the electronic device out of the inner side surfaces (t1, t2, t3, and t4) thereof, and having contact with the line m₂.

Further, FIG. 3B shows the result of the simulation of the stress ratio of each of the devices shown in FIGS. 4B and 4C with respect to the stress in the electronic device shown in FIG. 4A. As shown in the drawing, assuming that the stress in the electronic device shown in FIG. 4A is 1, the stress ratio in the electronic device having the side surface recessed sections 78 formed in the area A shown in FIG. 4B is obtained as 0.9. As described above, the smaller the distance from the center of the base substrate is, the larger the stress caused in the base substrate 12 is. Therefore, by forming the side surface recessed sections 78 inside the area A, the stress ratio can be suppressed to 0.9 or lower.

Then, in the electronic device having the side surface recessed sections 78 formed in the area B shown in FIG. 4C, the stress ratio of approximately 0.75 is obtained. Therefore, by forming the side surface recessed sections 78 inside the area B, the stress ratio can be suppressed to 0.75 or lower.

It should be noted that although the verification result of the case of forming the side surface recessed sections 78 in the longitudinal sides of the base substrates 12a, 12b, and 12c is obtained by the simulation described above, a small stress acts also in the short side direction of the base substrates 12a, 12b, and 12c. In this case, similarly to the case of forming the side surface recessed sections 78 in the longitudinal sides as shown in FIG. 1B, in the case of forming the side surface recessed sections 78 in the side surfaces in the short side direction, by forming the side surface recessed sections 78 inside the area A between the extended lines l₁ and l₂ passing through the outer side surfaces (s2, s4) of the frame member 70 substantially parallel to the longitudinal direction of the electronic device out of the outer side surfaces (s1, s2, s3, and s4) thereof, or inside the area B between the extended lines m₁ and m₂ passing through the inner side surfaces (t2, t4) of the frame member 70 substantially parallel to the longitudinal direction of the electronic device out of the inner side surfaces (t1, t2, t3, and t4) thereof, the effect of reducing the stress can be obtained.

According to the fact described hereinabove, it is preferable to form the side surface recessed sections 78 on the side surfaces of the base substrate 12 on the side thereof where the resonator element 80 is fixed in a plan view of the base substrate 12, and at positions where at least a part of the side surface recessed section overlaps the area A between the extended lines l₁ and l₂ obtained by extending the respective outer side surfaces of the frame member 70 opposed to each other.

More preferably, the side surface recessed sections are formed at positions on the side surfaces of the base substrate 12 on the side thereof where the resonator element 80 is fixed in a plan view of the base substrate 12, and in the area B between the extended lines m₁ and m₂ obtained by extending the respective inner side surfaces of the frame member 70 opposed to each other.

It should be noted that the corner castellations (76a, 76b, 76c, and 76d) each have a quadrant shape, and have the area smaller than the semicircular shape of the side surface recessed sections. Therefore, there can be obtained the structure hard for the crack to occur even in the case in which the stress is concentrated. Further, since the corner castellations (76a, 76b, 76c, and 76d) are disposed adjacent to the respective mounting terminals (61, 62, 63, and 64) in the plan view, an only little stress acts thereon with respect to the stress acting on the base substrate due to deformation of the user board. As described above, the corner castellations (76a, 76b, 76c, and 76d) have a little effect of reducing the stress of the base substrate compared to the side surface recessed section 78.

Then, a specific relation of the connections between the resonator element mounting terminals, the IC chip mounting terminals, and the lead wires when stacking the first through third substrates 20, 40, and 60 with each other will hereinafter be explained.

The first resonator element mounting terminal 41 is electrically connected to a first lead wire 52a via a first via-hole 50a. The first lead wire 52a is electrically connected to a second lead wire 52b via a second via-hole 50b. The second lead wire 52b is electrically connected to the fifth IC chip mounting terminal 47 in the middle of the wire, and a third via-hole 50c is formed at the end thereof. The second lead wire 52b is electrically connected to a third lead wire 52c via the third via-hole 50c, and is electrically connected to the side surface terminal 79a of the side surface recessed section 78a. Thus, the first resonator element mounting terminal 41 is electrically connected to the fifth IC chip mounting terminal 47 and the side surface terminal 79a of the side surface recessed section 78a.

The second resonator element mounting terminal 42 is electrically connected to the sixth IC chip mounting terminal 48 via a fourth lead wire 52d, and a fourth via-hole 50d is formed in the middle of the wire. The fourth lead wire 52d is electrically connected to a fifth lead wire 52e via the fourth via-hole 50d, and is electrically connected to the side surface terminal 79b of the side surface recessed section 78b. Thus, the second resonator element mounting terminal 42 is electrically connected to the sixth IC chip mounting terminal 48 and the side surface terminal 79b of the side surface recessed section 78b.

The first IC chip mounting terminal 43 is electrically connected to a sixth lead wire 52f via a fifth via-hole 50e. A sixth lead wire 52f is electrically connected to the first mounting terminal 61 via a sixth via-hole 50f. Thus, the first IC chip mounting terminal is electrically connected to the first mounting terminal 61.

The second IC chip mounting terminal 44 is electrically connected to a seventh lead wire 52g and a seventh via-hole 50g. The seventh lead wire 52g is electrically connected to the frame member 70 and the lid member 72 via the via-hole 23. Further, the second IC chip mounting terminal 44 is electrically connected to an eighth lead wire 52h via the seventh via-hole 50g. The eighth lead wire 52h is electrically connected to the fourth mounting terminal 64 via an eighth via-hole 50h. Thus, the second IC chip mounting terminal 44 is electrically connected to the lid member and the fourth mounting terminal 64.

The third IC chip mounting terminal 45 is electrically connected to the third mounting terminal 63 via a ninth lead wire 52i, a ninth via-hole 50i, and a tenth via-hole 50j. Thus, the third IC chip mounting terminal 45 is electrically connected to the third mounting terminal 63.

The fourth IC chip mounting terminal 46 is electrically connected to an eleventh lead wire 52k via a tenth lead wire 52j and an eleventh via-hole 50k. the eleventh lead wire 52k is electrically connected to the second mounting terminal 62 via a twelfth via-hole 50l. Thus, the fourth IC chip mounting terminal 46 is electrically connected to the second mounting terminal 62.

Then, the manufacturing method of the electronic device 10 according to the embodiment having the configuration described above will hereinafter be explained.

After stacking and then bonding the first through third substrates 20, 40, and 60 to each other, the resonator element 80 and the IC chip 90 are mounted on the second substrate 40. The electronic device 10 has the resonator element 80 and the IC chip 90 to be the electronic component arranged on one of the principal surfaces of the base substrate in the longitudinal direction thereof.

Specifically, the mounting electrodes of the resonator element 80 and the resonator element mounting terminals of the second substrate 40 are electrically connected to each other. Further, the plurality of electrode pads of the IC chip 90 is electrically connected to the corresponding IC chip mounting terminals, respectively. More specifically, resonator element connecting terminals, power supplying terminals, ST terminals, signal output terminals, grounding terminals, and so on of the IC chip 90 are electrically connected to the IC chip mounting terminals on the second substrate 40 composed of the mounting electrodes, the power supplying electrodes, the stand-by (ST) electrodes, the signal output electrodes, and the grounding electrodes respectively corresponding thereto.

Subsequently, the metal brazing material 24 is applied along the outer periphery of the first recessed section 21 of the first substrate 20, and then the frame member 70 is mounted thereon and then bonded thereto. As the bonding method, a liquid phase diffusion bonding method (hereinafter referred to as a transient liquid phase (TLP) bonding) can be adopted, as an example.

Further, the lid member 72 is mounted on the frame member 70 so as to cover the first recessed section 21, and is then bonded thereto. Subsequently, after the gap between the IC chip 90 and the second substrate 40 is filled with the resin material 74, the side surfaces of the IC chip 90 are covered with the resin material 74, and the resin material 74 are cured, the electronic device 10 can be obtained.

According to such an electronic device 10 of the present embodiment, the box-like structure composed of the frame member and the lid member is provided to the resonator element side of the base substrate, thus the base substrate can be reinforced. Since the side surface recessed sections are formed so that at least a part of the side surface recessed section overlaps the side surface area between the extended lines of the opposing outer side surfaces of the frame member intersecting the side surface of the base substrate, it is possible to effectively prevent the phenomenon that the stress is concentrated to the side surface recessed sections to cause the crack. Further, since the side surface terminals of the side surface recessed sections are exposed to the outside even after the piezoelectric device is coated with the resin material, frequency adjustment or the like of the resonator element can easily be performed.

The entire disclosure of Japanese Patent Application No. 2010-055974, filed Mar. 12, 2010 is expressly incorporated by reference herein.

What is claimed is:

1. An electronic device comprising:
a resonator element;
a base substrate having a substantially rectangular shape, having the resonator element fixed to one of principal surfaces, having a mounting terminal formed on the other of the principal surfaces, and provided with a lead wire;
a frame member having a substantially rectangular shape, disposed on the one of the principal surfaces so as to surround a periphery of the resonator element; and
a lid member adapted to cover an opening of the frame member,
wherein a side surface of the base substrate is provided with a side surface recessed section having a terminal electrically connected to the lead wire, and
the side surface recessed section is disposed on the side surface of the base substrate on a side where the resonator element is fixed, at a position where at least a part of the side surface recessed section overlaps an area between two extended lines passing through respective outer side surfaces of the frame member opposed to each other in a plan view from the one of the principal surfaces of the base substrate.

2. The electronic device according to claim 1, wherein
the side surface recessed section is disposed on the side surface of the base substrate on the side where the resonator element is fixed, in the area between the two extended lines passing through the respective outer side surfaces of the frame member opposed to each other in a plan view from the one of the principal surfaces of the base substrate.

3. The electronic device according to claim 1, wherein
the side surface recessed section is disposed on the side surface of the base substrate on the side where the resonator element is fixed, within an area between two extended lines passing through respective inner side surfaces of the frame member opposed to each other in a plan view from the one of the principal surfaces of the base substrate.

4. The electronic device according to claim 1, wherein
the frame member is a metal ring.

5. The electronic device according to claim 1, wherein
the lid member is a metal lid.

6. The electronic device according to claim 1, wherein
the resonator element and an electronic component are arranged on the one of the principal surfaces of the base substrate in a longitudinal direction of the base substrate.

7. The electronic device according to claim 6, wherein
the side surface recessed section is provided alone to the side surface on the resonator element side of the base substrate.
